(19) United States
(12) Patent Application Publication
(10) Pub. No.: US 2021/0195789 A1
(43) Pub. Date: Jun. 24, 2021

(54) HEAT DISSIPATION ASSEMBLY, HEAT DISSIPATION DEVICE, AND UNMANNED AERIAL VEHICLE

(71) Applicant: SZ DJI TECHNOLOGY CO., LTD., Shenzhen (CN)

(72) Inventor: Yang LI, Shenzhen (CN)

(21) Appl. No.: 17/173,104

(22) Filed: Feb. 10, 2021

Related U.S. Application Data
(63) Continuation of application No. PCT/CN2018/100872, filed on Aug. 16, 2018.

(51) Int. Cl. H05K 7/20; B64C 39/02

(52) U.S. Cl. CPC H05K 7/20145; B64C 2201/042; B64C 2201/027; B64C 39/024

(57) ABSTRACT

A heat dissipation assembly includes a fan and a heat conduction member connected to the fan. The fan includes an air outlet. An end of the heat conduction member cooperates with the air outlet of the fan and another end of the heat conduction member is provided with a plurality of flow outlets that are grouped into at least two groups facing different directions. Airflow from the air outlet of the fan flows through the heat conduction member and then flows out through the plurality of flow outlets.

### CROSS-REFERENCE TO RELATED APPLICATION

This application is a continuation of International Application No. PCT/CN2018/100872, filed Aug. 16, 2018, the entire content of which is incorporated herein by reference.

### TECHNICAL FIELD

The present disclosure relates to the field of heat dissipation technology and, more particularly, to a heat dissipation assembly, a heat dissipation device, and an unmanned aerial vehicle.

### BACKGROUND

There are a large number of heat generation elements in electronic equipment. The heat emitted by the heat generation elements needs to be exported in time to ensure the normal operation of the electronic equipment. At present, the heat is dissipated by setting a fan in the electronic equipment or by conducting heat through a housing of the electronic equipment. Correspondingly the heat accumulated in the electronic equipment is exported outside, such that the electronic equipment is prevented from failing to work normally due to heat accumulation. In the above heat dissipation method, the direction of the airflow in the electronic equipment is not planned, and part of the airflow is led out without sufficient heat exchange. Correspondingly, the utilization rate of the airflow is low, resulting in low heat dissipation efficiency.

### SUMMARY

In accordance with the disclosure, there is provided a heat dissipation assembly including a fan and a heat conduction member connected to the fan. The fan includes an air outlet. An end of the heat conduction member cooperates with the air outlet of the fan and another end of the heat conduction member is provided with a plurality of flow outlets that are grouped into at least two groups facing different directions. Airflow from the air outlet of the fan flows through the heat conduction member and then flows out through the plurality of flow outlets.

Also in accordance with the disclosure, there is provided an unmanned aerial vehicle including a vehicle body including a receiving space and provided with an airflow exit, a circuit board, and heat dissipation assembly connected to the circuit board. The circuit board and the heat dissipation assembly are accommodated in the receiving space. The heat dissipation assembly includes a fan and a heat conduction member connected to the fan. The fan includes an air outlet. An end of the heat conduction member cooperates with the air outlet of the fan and another end of the heat conduction member is provided with a plurality of flow outlets that are grouped into at least two groups facing different directions. Airflow from the air outlet of the fan flows through the heat conduction member and then flows out through the plurality of flow outlets.

### BRIEF DESCRIPTION OF THE DRAWINGS

The above and/or additional aspects and advantages of this disclosure will become obvious and easy to understand from the description of the embodiments in conjunction with the following drawings.

FIG. 1 is a perspective view of an exemplary heat dissipation assembly consistent with various embodiments of the present disclosure.

FIG. 2 is an exploded view of an exemplary heat dissipation assembly consistent with various embodiments of the present disclosure.

FIG. 3 is an exploded view of an exemplary heat dissipation device consistent with various embodiments of the present disclosure.

FIG. 4 is an exploded view of another exemplary heat dissipation device consistent with various embodiments of the present disclosure.

FIG. 5 is a perspective view of an exemplary heat dissipation device consistent with various embodiments of the present disclosure.

FIG. 6 is a partial enlarged view of the heat dissipation device in FIG. 5.

FIG. 7 is a perspective view of an unmanned aerial vehicle consistent with various embodiments of the present disclosure.

FIG. 8 is an exploded view of an unmanned aerial vehicle consistent with various embodiments of the present disclosure.

FIG. 9 is a perspective view of another unmanned aerial vehicle consistent with various embodiments of the present disclosure.

FIG. 10 is a perspective view of another unmanned aerial vehicle consistent with various embodiments of the present disclosure.

FIG. 11 is an exploded view of another unmanned aerial vehicle consistent with various embodiments of the present disclosure.

### REFERENCE NUMERALS

100: vehicle body; 101: main body; 102: upper cover; 103: lower cover; 104: front cover; 105: rear cover; 110: receiving space; 120: airflow exit; 121: first airflow exit; 122: second airflow exit; 123: third airflow exit; 130: air inlet member; 140: first side wall; 150: second side wall; 160: third side wall;
200: circuit board; 210: first circuit board; 201: first area; 202: second area; 203: third area; 204: functional device; 205: positioning member; 220: second circuit board; 230: third circuit board;
300: heat dissipation assembly; 1: fan; 11: first air outlet; 12: first air inlet; 13: housing; 13a: fixed end; 14: fan blade; 2: heat conduction member; 21: flow outlet; 211: first flow outlet; 212: second flow outlet; 213: third flow outlet; 22: main body; 221: first mounting member; 23: heat conduction sheet; 231: heat dissipation rib; 24: cover body; 241: second mounting member; 3: damping member; 4: fastener;
400: arm;
500: gimbal;
600: Battery assembly.

### DETAILED DESCRIPTION OF THE EMBODIMENTS

Technical solutions of the present disclosure will be described with reference to the drawings. It will be appreciated that the described embodiments are part rather than all of the embodiments of the present disclosure. Other embodiments conceived by those having ordinary skills in the art on the basis of the described embodiments without inventive efforts should fall within the scope of the present disclosure.

Example embodiments will be described with reference to the accompanying drawings, in which the same numbers refer to the same or similar elements unless otherwise specified.

As used herein, when a first component is referred to as “fixed to” a second component, it is intended that the first component may be directly attached to the second component or may be indirectly attached to the second component via another component. When a first component is referred to as “connecting” to a second component, it is intended that the first component may be directly connected to the second component or may be indirectly connected to the second component via a third component between them. The terms “perpendicular,” “horizontal,” “left,” “right,” and similar expressions used herein are merely intended for description.

Unless otherwise defined, all the technical and scientific terms used herein have the same or similar meanings as generally understood by one of ordinary skill in the art. As described herein, the terms used in the specification of the present disclosure are intended to describe example embodiments, instead of limiting the present disclosure. The term “and/or” used herein includes any suitable combination of one or more related items listed.

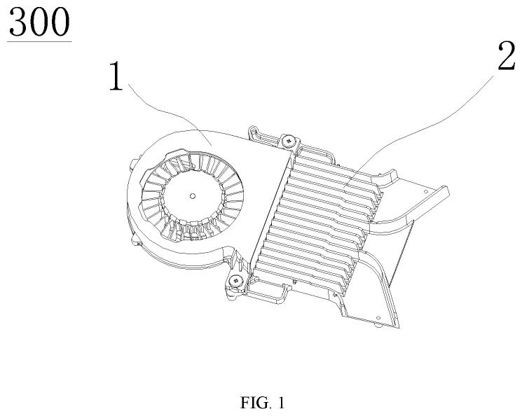

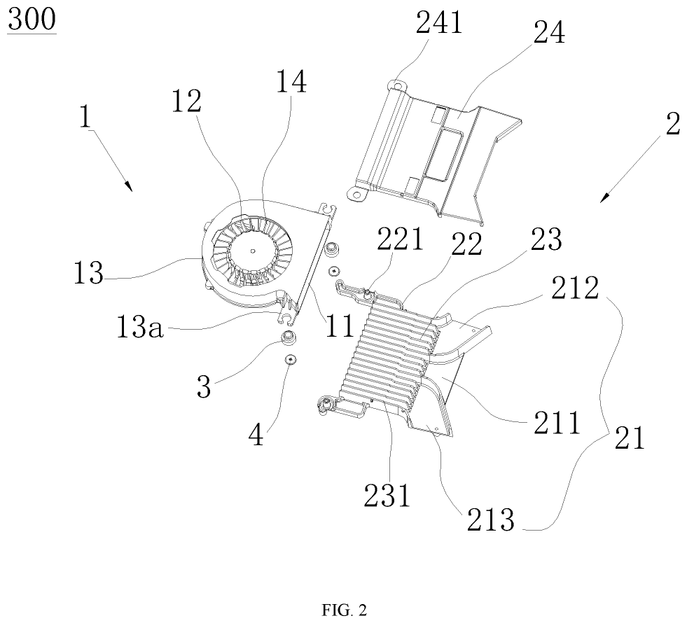

FIG. 1 and FIG. 2 show a heat dissipation assembly 300 consistent with the disclosure. The heat dissipation assembly 300 includes a fan 1 and a heat conduction member 2 connected to the fan 1. The fan 1 includes a first air outlet 11. One end of the heat conduction member 2 cooperates with the first air outlet 11. A plurality of flow outlets 21 are disposed at another end of the heat conduction component 2. In some embodiments, airflow flowing out from the first air outlet 11 may flow through the heat conduction member 2 and then flow out via the plurality of flow outlets 21. When the airflow flows through the heat conduction member 2, it may contact the heat conduction member 2 efficiently, to take away the heat accumulated in the heat conduction member 2 and achieve sufficient heat exchange.

Further, the plurality of flow outlets 21 include at least two groups of flow outlets. The at least two groups of flow outlets 21 face different directions. Part of the airflow from the at least two groups of flow outlets 21 flows directly to the outside of the electronic device, and the other part of the airflow from the at least two groups of airflow outlets 21 directly dissipates the main heat generation elements in the electronic device, to achieve high heat dissipation efficiency.

In various embodiments, the plurality of flow outlets 21 may include two, three, four, or more groups of flow outlets. A number of the plurality of flow outlets 21 may be determined according to a shape of the electronic device, heat dissipation requirement of the electronic device, distribution of the heat generation elements. In some embodiments, as illustrated in FIG. 2, the plurality of flow outlets 21 include a first flow outlet 211, a second flow outlet 212, and a third flow outlet 213. The second flow outlet 212 and the third flow outlet 213 are disposed at two sides of the first flow outlet 211, respectively. In some embodiments, the airflow from the first flow outlet 211 can directly dissipate the heat of the heat generation elements. For example, the first flow outlet 211 may be disposed close to or directly aligned with the heat generation elements. The airflow from the second flow outlet 212 and the third flow outlet 213 can be directly exported to the outside of the electronic device.

Further, in some embodiments, as illustrated in FIG. 1 and FIG. 2, outlet directions of the first flow outlet 211, the second flow outlet 212, and the third flow outlet 213 are different from each other, such that the airflow from the first air outlet 11 is directed to different directions to meet different requirements.

Further, in some embodiments, the first flow outlet 211 gradually enlarges in a direction away from the first air outlet 11, such that the airflow from the first air outlet 211 can flow out from multiple directions, thereby dissipating heat from heat generation elements in different directions.

In some embodiments, the heat conduction member 2 is further provided with an air inlet, and the air inlet cooperates with the first air outlet 11, such that the airflow from the first air outlet 11 can be introduced into the heat conduction member 2. The airflow from the first air outlet 11 flows into the heat conduction member 2 through the air inlet, and then flows out from the plurality of flow outlets 21. In some embodiments, the air inlet is provided at an end of the heat conduction member 2 close to the first air outlet 11, and the plurality of flow outlets 21 is provided at an end of the heat conduction member 2 away from the first air outlet 11.

In various embodiments, the heat dissipation assembly may include one or more air inlets, and the specific number of the one or more air inlets may be determined according to the shape of the electronic device, the heat dissipation requirement of the electronic device, or the distribution of the heat generation elements. Further, the number of the one or more air inlets may be same as or different from the number of the plurality of flow outlets 21.

In some embodiments, as illustrated in FIG. 2, the heat conduction member 2 includes a main body 22 connected to the fan 1 and at least three barriers provided at the main body 22. Each barrier extends from an end of the main body 22 close to the first air outlet 11 to another end of the main body 22 away from the first air outlet 11. An airflow channel is formed between every two adjacent barriers, and an end of each airflow channel close to the first air outlet 11 forms an airflow inlet. Another end of each airflow channel far away from the first air outlet 11 forms one of the plurality of flow outlets 21. The airflow flowing out of the first air outlet 11 flows into corresponding one of the airflow channels through each air inlet and fully exchanges heat, and then flows out from one of the plurality of flow outlets 21 corresponding to the airflow channel, to achieve the purpose of heat exchange.

Further, as illustrated in FIG. 2, the heat conduction member 2 further includes a plurality of heat conduction sheets 23 arranged at the main body 22. The plurality of heat conduction sheets 23 is arranged at intervals. Each heat conduction sheet 23 of the plurality of heat conduction sheets 23 can be extended from the air inlets (that is, the end of the body 22 close to the first air outlet 11) to the plurality of flow outlets 21, such that a heat exchange area of each heat conduction sheet 23 is large. When the airflow flows through the plurality of heat conduction sheets 23, it can exchange heat more sufficiently. In some embodiments, the airflow flowing out of the first air outlet 11 flows in through the air inlets, and then flows out from the plurality of flow outlets 21 after flowing through the plurality of heat conduction sheets 23. The airflow fully contacts the plurality of heat conduction sheets 23 to take away the heat on the plurality of heat conduction sheets 23, to achieve sufficient heat dissipation.

In some embodiments, as illustrated in FIG. 2, an extension direction of the plurality of heat conduction sheets 23 is consistent with an extension direction of the barriers. The barriers may be made of a thermally conductive material (such as a thermally conductive metal) or a non-thermally conductive material. In some embodiments, the barriers and the plurality of heat conduction sheets 23 may be a same component. The shape and material of the barriers and the plurality of heat conduction sheets 23 may be same. That is, the barriers may be the plurality of heat conduction sheets 23. When the air flows through the barriers, the heat on the barriers can be taken away, improving the heat exchange effect. In some other embodiments, the barriers are non-thermally conductive components.

The plurality of heat conduction sheets 23 may be arranged in each airflow channel or a portion of the airflow channels. Optionally, the airflow channels may be provided with the plurality of heat conduction sheets 23 arranged at intervals, and sub-airflow channels may be formed between the plurality of heat conduction sheets 23 and between the barriers and a portion of the heat conduction sheets 23. Correspondingly, the airflow from the first air outlet 11 may flow through these sub-airflow channels, to achieve full heat exchange and improve the utilization rate of the airflow.

As illustrated in FIG. 2, a side of each heat conduction sheet 23 away from the main body 22 is provided with an auxiliary heat dissipation rib 231, to increase the heat exchange area. Correspondingly, the heat exchange efficiency of the airflow is further improved. In some embodiments, each auxiliary heat dissipation rib 231 extends from the end of the main body 22 close to the first air outlet 11 to the middle of the corresponding heat conduction sheet 23, and each auxiliary heat dissipation rib 231 and the corresponding heat conduction sheet 23 form a heat dissipation step. The material of the auxiliary heat dissipation ribs 231 and the material of the plurality of heat conduction sheets 23 may be the same or different. Also, each auxiliary heat dissipation rib 231 may be integrally formed at the corresponding heat conduction sheet 23, or be connected to the corresponding heat conduction sheet 23.

In various embodiments, the main body 22 may be made of a thermally conductive material (including a thermally conductive metal) or a non-heat conductive material. For example, in some embodiments, the main body 22 may be made of a thermally conductive material. Optionally, the material of the plurality of heat conduction sheets 23 may be same as the material of the main body 22. The plurality of heat conduction sheets 23 may be integrally formed at the main body 22, or may be connected to the main body 22 through, e.g., plug connection or lock connection. Further, optionally, the barriers may be made of a material same as the material of the main body 22. The barriers may be integrally formed at the main body 22, or may be connected to the main body 22 through, e.g., plug connection or lock connection.

In some other embodiments, the main body 22 may be made of a non-thermally conductive material. Optionally, the material of the barriers may be the same as the material of the main body 22, and the barriers may be integrally formed at the main body 22, or connected to the main body 22 by, e.g., lock connection or plug connection. The plurality of heat conduction sheets 23 can be connected to the main body 22 by, e.g., lock connection or plug connection.

In some embodiments where the plurality of heat conduction sheets 23 is connected to the main body 22, a manner which is used to connect the plurality of heat conduction sheets 23 to the main body 22 may be selected according to the actual needs. For example, in some embodiments, a plurality of plug interfaces may be formed at the main body 22, and the plurality of heat conduction sheets 23 may be matched with the plurality of plug interfaces one by one. The plurality of plug interfaces may be through holes or plug slots, which can be selected according to the actual needs.

As illustrated in FIG. 2, the fan 1 includes a casing 13 and fan blades 14 arranged at the casing 13. The casing 13 is connected to the main body 22. In some embodiments, the first air outlet 11 of the fan 1 is provided at the housing 13. When the fan 1 is working, the airflow generated by the rotation of the fan blades 14 is led out from the first air outlet 11 and enters the airflow channels on the heat conduction member 2.

In some embodiments, the housing 13 is a thermally conductive component, that is, the housing 13 is made of a thermally conductive material (such as a thermally conductive metal). In some embodiments, the fan 1 not only functions as a wind source power, but also has a heat conduction function and directly participates in heat conduction. Specifically, when the fan 1 is in use, the housing 13 can directly or indirectly contact the heat generation elements in the electronic device, to conduct heat, absorb the heat on the heat generation element and further improve the heat dissipation efficiency. The housing 13 can be made of a thermally conductive material with higher thermal conductivity which can be specifically selected according to needs, and this disclosure does not specifically limit this.

The fan 1 further includes a first air inlet 12. When the heat dissipation assembly 300 is installed in the electronic device, the first air inlet 12 can be matched with the air inlet member 130 of the electronic device or the gap on the housing of the electronic device, to suck in the external airflow. The airflow then is exported from the first air outlet 11.

In various embodiments, the fan 1 can be a centrifugal fan or another type of fan.

To reduce the impact of the vibration generated during the operation of the fan 1 on the heat conduction member 2, the heat dissipation assembly 300 further includes a damping member 3. The damping member 3 is arranged at the junction of the housing 13 and the main body 22. In some embodiments, the housing 13 and the main body 22 are connected by the damping member 3. Correspondingly, the main body 22 is less affected by the vibration of the fan 1, thereby reducing the influence of the main body 22 on some heat generation elements of the electronic device that are sensitive to vibration.

Specifically, as illustrated in FIG. 2, the housing 13 is provided with a fixed end 13a, and the main body 22 is provided with a first mounting member 221. In some embodiments, the first mounting member 221 is connected to the fixed end 13a, and the damping member 3 is disposed between the first mounting member 221 and the fixed end 13a. Specifically, the first mounting member 221 is a plug-in portion, and the fixed end 13a is a plug-in slot. The plug-in portion and the plug-in slot may be plug to match, and the damping member 3 is sleeved on the plug-in portion.

To improve the stability of the connection between the housing 13 and the main body 22, a plurality of fixed ends 13a may be provided. For example, two fixed ends 13a may be provided, and the two fixed ends 13a may be respectively provided at two sides of the housing 13 respectively. Correspondingly, two first mounting members 221 may be provided and the two first mounting members 221 may be respectively provided at two sides of the main body 22. The two first mounting members 221 may be connected to the two fixed ends 13a respectively.

The type of the damping member 3 may be selected according to needs. Optionally, the damping member 3 may be an elastic piece. In some embodiments, the damping member 3 may be made of an elastic material. In other embodiments, the damping member 3 may be an elastic structure including a spring.

Further, as illustrated in FIG. 2, in some embodiments, the heat dissipation assembly 300 further includes a cover body 24, and the cover body 24 is disposed at the heat conduction member 2. Specifically, the cover body 24 and the main body 22 are matched, such that the airflow channels on the heat conduction member 2 form sealed airflow channels. Further, the cover body 24 can have outlets at positions corresponding to the plurality of flow outlets 21 to ensure that the airflow passing through the heat conduction member 2 can flow out from the plurality of flow outlets 21.

The cover body 24 and the main body 22 can be integrally formed, or can be provided separately. In some embodiments, the cover body 24 and the main body 22 are provided separately, and the cover body 24 is provided at the main body 22. The airflow channels can be sealed in the space formed by the main body 22 and the cover body 24, thereby ensuring the heat dissipation effect. Further, there is no need to provide a separate external structure to seal the airflow channel, and the structure is simple.

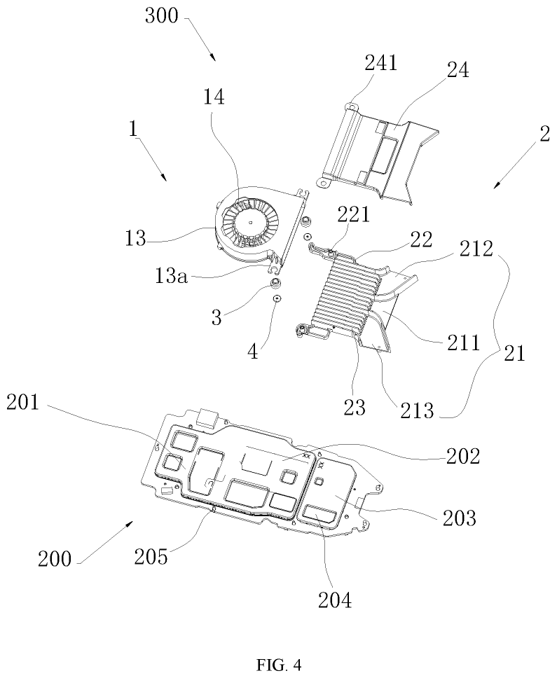

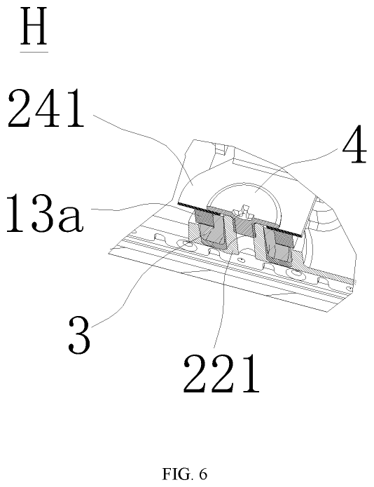

Further, as illustrated in FIG. 2, FIG. 4, and FIG. 6, the cover body 24 is provided with a second mounting member 241. After the first mounting member 221 passes through the fixing end 13a, it is fixedly connected to the second mounting member 241, improving the firmness of the connection between the housing 13 and the main body 22. Furthermore, the heat dissipation assembly 300 further includes a fastener 4 that fixes the second mounting member 241 on the first mounting member 221 to further improve the firmness of the connection between the housing 13 and the main body 22. The fastener 4 may be a nut or another fastening structure.

The cover body 24 may be made of a thermally conductive material (such as a thermally conductive metal). When the airflow flows through the airflow channels, it can take away the heat on the cover body 24 and further improve the heat dissipation efficiency.

In the heat dissipation assembly 300 of the embodiment of the present disclosure, the airflow from the fan 1 may pass through the heat conduction member 2 and then flow out from at least two sets of flow outlets 21 facing different directions. The heat conduction member 2 may absorb heat nearby and the airflow flowing through the heat conduction member 2 may fully contact the heat conduction member 2 to fully exchange heat, improving the utilization rate of the airflow and enhancing the heat exchange effect. Further, the airflow from the plurality of flow outlets 21 may also directly dissipate the heat generated by the main heat generation elements in the electronic device, and the heat dissipation efficiency may be high. The heat dissipation assembly 300 of the present disclosure may use the airflow for heat dissipation more efficiently and evenly.

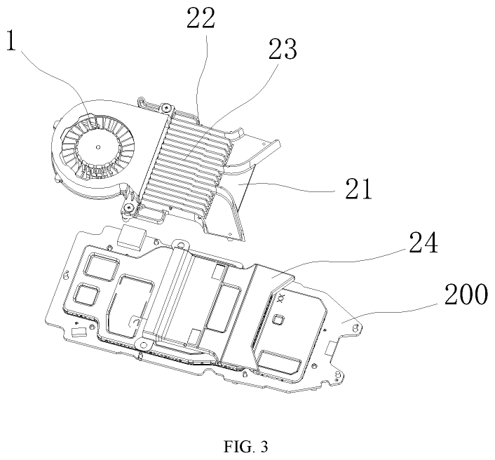

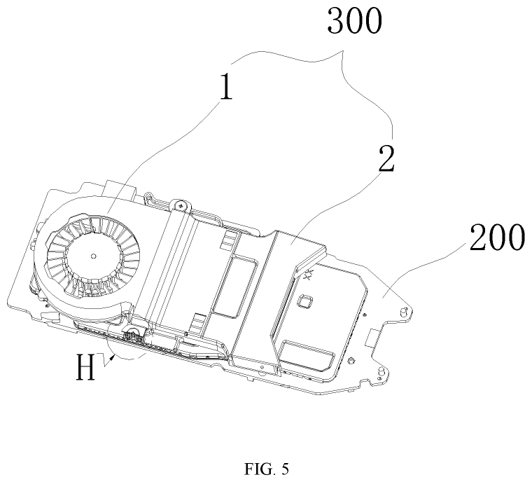

The heat dissipation assembly 300 provided by various embodiments of the present disclosure may be applied to various electronic devices or structures that require heat dissipation. For example, in some embodiments, as illustrated in FIG. 3 to FIG. 5, the heat dissipation assembly 300 is applied to a circuit board 200. The heat generated by various electronic components on the circuit board 200 is dissipated. In other embodiments, the heat dissipation assembly 300 may be applied to electronic devices including unmanned aerial vehicles or remote-control vehicles, to dissipate heat of the electronic devices and ensure the normal operation of the electronic devices.

In the following, examples where the heat dissipation assembly 300 is applied to a circuit board 200 or an unmanned aerial vehicle are described.

FIG. 3 to FIG. 5 show a heat dissipation device consistent with the disclosure. The heat dissipation device includes a circuit board 200 and a heat dissipation assembly 300 connected to the circuit board 200. The heat dissipation assembly 300 have structures, functions, working principles and effects similar to the example heat dissipation assembly above, and description thereof will not be repeated here. The circuit board 200 and the heat dissipation assembly 300 are combined to form the heat dissipation device. When the circuit board 200 is subjected to a single test, the heat dissipation assembly 300 can dissipate heat of the circuit board 200 without the need for other air sources or components to assist heat dissipation.

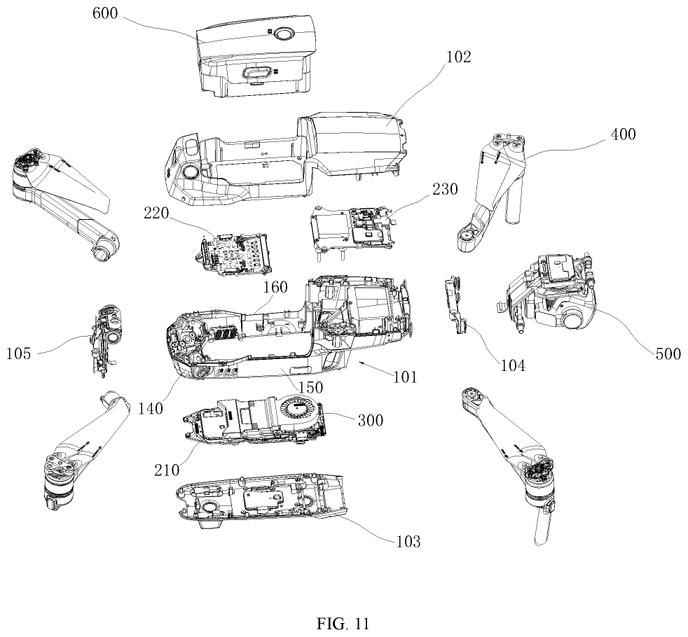

In some embodiments, as illustrated in FIG. 11, the circuit board 200 includes a first circuit board 210 and a second circuit board 220. The first circuit board 210 is disposed at one side of the heat dissipation assembly 300, and the second circuit board 220 is disposed at another side of the heat dissipation assembly 300. Optionally, the first circuit board 210 is arranged under the fan 1 and the heat conduction member 2 (that is, a side of the main body 22 away from the plurality of heat conduction sheets 23), and the second circuit board 220 is arranged above the heat conduction member 2.

The arrangement of the heat dissipation assembly 300 and the first circuit board 210 can be selected according to needs. For example, in some embodiments, the first circuit board 210 may be attached to one side of the heat dissipation assembly 300. In some embodiments, the first circuit board 210 may be attached below the housing 13 of the fan 1 and the main body 22 of the heat conduction member 2. Correspondingly, the heat dissipation assembly 300 can better dissipate the heat on the first circuit board 210. In another embodiment, the first circuit board 210 may be disposed below the heat dissipation component 300 at a first interval from the heat dissipation assembly 300. The smaller the first interval is, the better the heat dissipation effect of the heat dissipation assembly 300 on the first circuit board 210 is achieved. For example, the first interval may be 0.1 mm, 0.2 mm, 0.3 mm, 0.4 mm, or 0.5 mm.

The arrangement of the heat dissipation assembly 300 and the second circuit board 220 can be selected according to needs. For example, in some embodiments, the second circuit board 220 may be attached to another side of the heat dissipation assembly 300. In some embodiments, the second circuit board 220 may be attached above the housing 13 of the fan 1 and the main body 22 of the heat conduction member 2. Correspondingly, the heat dissipation assembly 300 can better take away the heat on the second circuit board 220. In another embodiment, the second circuit board 220 may be disposed below the heat dissipation component 300 at a second interval from the heat dissipation assembly 300. The smaller the second interval is, the better the heat dissipation effect of the heat dissipation assembly 300 on the second circuit board 220 is achieved. For example, the second interval may be 0.1 mm, 0.2 mm, 0.3 mm, 0.4 mm, or 0.5 mm.

In some embodiments, the heat dissipation assembly 300 is connected to the first circuit board 210. Specifically, the main body 22 of the heat dissipation assembly 300 is connected to the first circuit board 210. In some embodiments, the damping member 3 of the heat dissipation assembly 300 is arranged between the housing 13 and the first circuit board 210. The damping member 3 can reduce the vibration force transmitted by the fan 1 to the first circuit board 210, thereby reducing the impact on some functional devices 204 on the first circuit board 210 that are sensitive to vibration. As illustrated in FIG. 6, the first circuit board 210 is provided with a positioning member 205, and the positioning member 205 is plug and connected to the first mounting member 221 on the main body 22. The first mounting member 221 is connected to the fixed end 13a on the housing 13. The damping member 3 on the heat dissipation assembly 300 is arranged between the first mounting member 221 and the fixed end 13a. In some embodiments, the positioning member 205 is a positioning protrusion, and the first mounting member 221 is provided with a mounting hole. The positioning protrusion is inserted into the mounting hole.

Further, in some embodiments, the heat dissipation assembly 300 and the second circuit board 220 are also connected. Specifically, the main body 22 of the heat dissipation assembly 300 is connected to the second circuit board 220, and the means for connecting the main body 22 and the second circuit board 220 can be any proper connection means. The heat dissipation assembly 300 is connected to the first circuit board 210 and the second circuit board 220 respectively to form an integral structure.

In some embodiments, the first circuit board 210 and a second circuit board 220 are respectively provided with a plurality of functional devices 204 that generate heat. The functional devices 204 may include chips, sensors, and the like. In some embodiments, the functional devices 204 may be chips, for example, including a control chip or a driver chip.

As illustrated in FIG. 4, in some embodiments, the first circuit board 210 includes a first area 201, a second area 202, and a third area 203. The fan 1 of the heat dissipation assembly 300 cooperates with the first area 201, the plurality of heat conduction sheets 23 of the heat conduction member 2 cooperates with the second area 202, and the at least one flow outlet 21 of the plurality of flow outlets 21 cooperates with the third area 203. In some embodiments, the fan 1 is made of a thermally conductive material, and the fan 1 is in contact with the first area 201 to conduct heat generated by the first area 201 to the heat conduction member 2. Specifically, the housing 13 of the fan 1 directly or indirectly contacts the functional devices 204 in the first area 201, to conduct the heat generated by the first area 201 to the heat conduction member 2. Further, in some embodiments, the heat conduction member 2 is in contact with the second area 202 to conduct heat conduction generated by the second area 202 and conduct the heat to the plurality of flow outlets 21. Specifically, the heat conduction member 2 directly or indirectly contacts the functional devices 204 in the second area 202 through the plurality of heat conduction sheets 23 and/or the main body 22 to conduct heat generated in the second area 202 and conduct the heat to the plurality of flow outlets 21. The airflow from the plurality of air outlets 21 flows directly or at intervals to the third area 203 to dissipate heat from the functional devices 204 in the third area 203.

To increase the heat dissipation speed in the third area 203, in some embodiments, at least one set of the plurality of flow outlets 21 may be aligned with the third area 203. Correspondingly, the third area 203 may be directly aligned with at least one flow outlet 21 of the plurality of flow outlets 21 and have high heat dissipation efficiency. In another embodiment, at least one flow outlet 21 of the plurality of flow outlets 21 may be arranged close to the third area 203, thereby increasing the heat dissipation speed of the third area 203.

Specifically, the airflow from the first flow outlet 211 of the heat dissipation assembly 300 may be aligned with or close to the third area 203.

When the heat of the second circuit board 220 is dissipated by the heat dissipation assembly 300, the plurality of heat conduction sheets 23 and/or the main body 22 of the heat conduction member 2 may be in contact with the second circuit board 220 to conduct the heat generated by the second circuit board 220 to the plurality of flow outlets 21. Specifically, the heat conduction member 2 may directly or indirectly contact the functional devices 204 on the second circuit board 220 through the plurality of heat conduction sheets 23 and/or the main body 22, to conduct the heat generated by the second circuit board 220 to the plurality of flow outlets 21.

In some embodiments, the heat dissipation device can be a part of the unmanned aerial vehicle. Optionally, the first circuit board 210 may be a main control board of the unmanned aerial vehicle, and the second circuit board 220 may be a motor drive circuit board of the unmanned aerial vehicle.

In the heat dissipation device of the present disclosure, the airflow from the fan 1 may pass through the heat conduction member 2 and then flow out from at least two sets of the plurality of flow outlets 21 facing different directions. On the one hand, the heat conduction member 2 may absorb the heat generated by the circuit board 200, and the airflow flowing through the heat conduction member 2 may fully contact the heat conduction member 2 to achieve a fully heat exchange. The utilization rate of the airflow may be improved and the heat exchange effect may be enhanced. On the other hand, the airflow flowing out from the plurality of flow outlets 21 may also directly dissipate the heat generated by the main heat generation elements in the electronic device, and the heat dissipation efficiency may be high. The heat dissipation assembly 300 of the present invention can use the airflow for heat dissipation more efficiently and evenly.

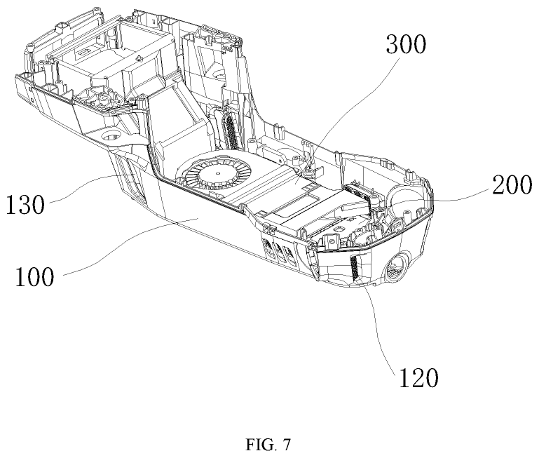

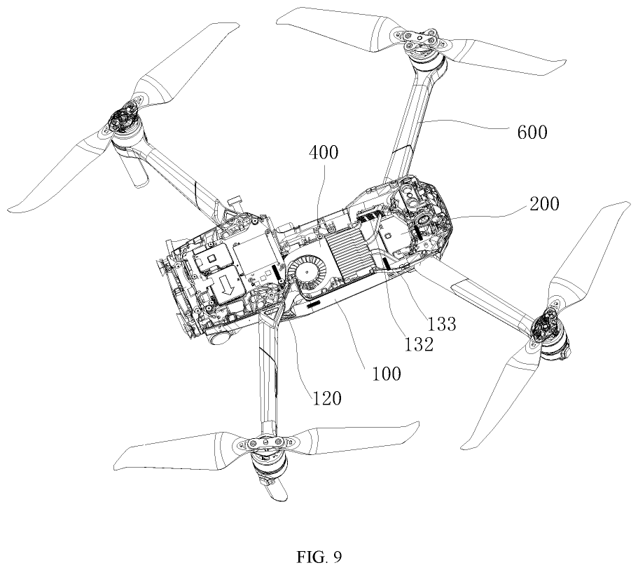

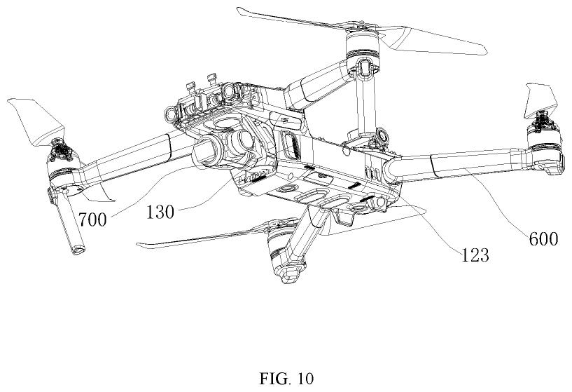

FIG. 7 to FIG. 11 show an unmanned aerial vehicle consistent with the disclosure. The unmanned aerial vehicle includes a vehicle body 100, a circuit board 200, and a heat dissipation assembly 300 connected to the circuit board 200. Further, the vehicle body 100 has a receiving space 110, and the circuit board 200 and the heat dissipation assembly 300 are both received in the receiving space 110. For the structure, function, working principle and effect of the heat dissipation assembly 300, reference can be made to the description of the heat dissipation assembly 300 above.

In some embodiments, the vehicle body 100 is provided with airflow exits 120. The airflow from the first air outlet 11 of the heat dissipation assembly 300 flows through the heat conduction member 2 and the plurality of flow outlets 21, and then exits the vehicle body 100 through the airflow exits 120, such that the heat in the receiving space 110 is taken away.

In some embodiments, a number of the airflow exits 120 may be, for example, two, three, or more than three. The multiple airflow exits 120 cooperate with the flow outlets 21, and the airflow from the flow outlets 21 is led to the outside of the vehicle body through the airflow exits 120. Specifically, the airflow exits 120 includes a first airflow exit 121, a second airflow exit 122, and a third airflow exit 123, which are respectively connected to the first air outlet 211, the second air outlet 212, and the third air outlet 213 of the heat dissipation assembly 300.

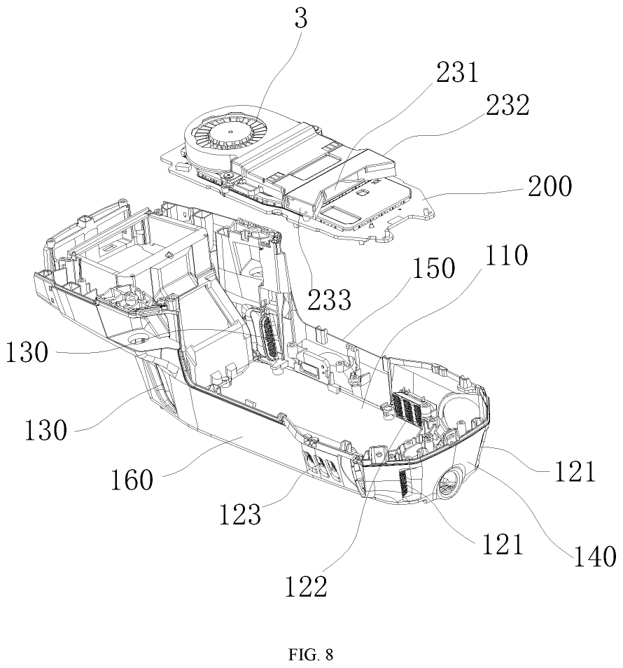

As illustrated in FIG. 8 and FIG. 11, the vehicle body 100 includes a first sidewall 140, a second sidewall 150, and a third sidewall 160. The first sidewall 140 is located at the rear of the vehicle body 100, and the second sidewall 150 and the third sidewall 160 are located on two sides of the first sidewall 140, respectively. The first airflow exit 121 is opened on the first sidewall 140, the second airflow exit 122 is opened on the side of the second sidewall 150 near the rear of the vehicle body 100, and the third airflow exit 123 is opened on a side of the third sidewall 160 close to the rear of the vehicle body 100. The positions where the first airflow exit 121, the second airflow exit 122, and the third airflow exit 123 are arranged at the vehicle body 100 are not limited to this. In various embodiments, the positions of the first airflow exit 121, the second airflow exit 121 and the second airflow exit 123 on the vehicle body 100 may be configured according to actual needs.

In various embodiments, the unmanned aerial vehicle may include a plurality of first airflow exits 121, and/or a plurality of second airflow exits 122, and/or a plurality of third airflow exits 123. For example, in some embodiments, two first airflow exits 121 may be provided at two sides of the first sidewall 140, respectively. Three second airflow exits 122 may be provided at the second sidewall 150, and may cooperate with the second flow outlet 212 to direct the airflow from the second flow outlet 212 to the outside of the vehicle body 100. Three third airflow exits 123 may be formed at the third sidewall 160 at intervals, and all of the three third airflow exits 123 may cooperate with the third flow outlet 213 to direct the airflow from the third flow outlet 213 to the outside of the vehicle body 100.

There may be multiple types of the airflow exits 120. For example, in some embodiments, each airflow exit 120 may include a plurality of second air outlets (the second air outlets may be circular, square or other shapes). In other embodiments, the airflow exits 120 may also be a grid structure.

As illustrated in FIG. 11, the vehicle body 100 includes a main body 101, an upper cover 102 disposed above the main body 101, a lower cover 103 disposed below the main body 101, a front cover 104 disposed in front of the main body 101, and a rear cover 105 disposed behind the main body 101. The main body 101, the upper cover 102 and the lower cover 103 surround and form the receiving space 110. The first sidewall 140 is formed by the main body 101 and the back cover 105. The second sidewall 150 and the third sidewall 160 are located on two sides of the main body 101, respectively. The composition of the vehicle body 100 is not limited to the above manner.

In some embodiments, as illustrated in FIG. 11, the circuit board 200 includes a first circuit board 210 and a second circuit board 220. The first circuit board 210 is disposed at one side of the heat dissipation assembly 300, and the second circuit board 220 is disposed at another side of the heat dissipation assembly 300. Optionally, the first circuit board 210 is arranged under the fan 1 and the heat conduction member 2 (that is, a side of the main body 22 away from the plurality of heat conduction sheets 23), and the second circuit board 220 is arranged above the heat conduction member 2.

The arrangement of the heat dissipation assembly 300 and the first circuit board 210 can be selected according to needs. For example, in some embodiments, the first circuit board 210 may be attached to one side of the heat dissipation assembly 300. In some embodiments, the first circuit board 210 may be attached below the housing 13 of the fan 1 and the main body 22 of the heat conduction member 2. Correspondingly, the heat dissipation assembly 300 can better take away the heat on the first circuit board 210. In another embodiment, the first circuit board 210 may be disposed below the heat dissipation component 300 at a first interval from the heat dissipation assembly 300. The smaller the first interval is, the better the heat dissipation effect of the heat dissipation assembly 300 on the first circuit board 210 is achieved. For example, the first interval may be 0.1 mm, 0.2 mm, 0.3 mm, 0.4 mm, or 0.5 mm.

The arrangement of the heat dissipation assembly 300 and the second circuit board 220 can be selected according to needs. For example, in some embodiments, the second circuit board 220 may be attached to another side of the heat dissipation assembly 300. In some embodiments, the second circuit board 220 may be attached above the housing 13 of the fan 1 and the main body 22 of the heat conduction member 2. Correspondingly, the heat dissipation assembly 300 can better take away the heat on the second circuit board 220. In another embodiment, the second circuit board 220 may be disposed below the heat dissipation component 300 at a second interval from the heat dissipation assembly 300. The smaller the second interval is, the better the heat dissipation effect of the heat dissipation assembly 300 on the second circuit board 220 is achieved. For example, the second interval may be 0.1 mm, 0.2 mm, 0.3 mm, 0.4 mm, or 0.5 mm.

In some embodiments, the heat dissipation assembly 300 is connected to the first circuit board 210. Specifically, the main body 22 of the heat dissipation assembly 300 is connected to the first circuit board 210. In some embodiments, the damping member 3 of the heat dissipation assembly 300 is arranged between the housing 13 and the first circuit board 210. The damping member 3 can reduce the vibration force transmitted by the fan 1 to the first circuit board 210, thereby reducing the impact on some functional devices 204 on the first circuit board 210 that are sensitive to vibration. As illustrated in FIG. 6, the first circuit board 210 is provided with a positioning member 205, and the positioning member 205 is plug and connected to the first mounting member 221 on the main body 22. The first mounting member 221 is connected to the fixed end 13a of the housing 13. The damping member 3 on the heat dissipation assembly 300 is arranged between the first mounting member 221 and the fixed end 13a. In some embodiments, the positioning member 205 is a positioning protrusion, and the first mounting member 221 is provided with a mounting hole. The positioning protrusion is inserted into the mounting hole.

Further, after the heat dissipation assembly 300 is connected to the first circuit board 210 and the second circuit board 220 respectively to form an integral structure, the first circuit board 210 may be connected to the inner sidewall of the vehicle body 100 using any proper connection manner.

Further, the second circuit board 220 may be connected to the inner sidewall of the vehicle body 100 using any proper connection manner.

In some embodiments, the first circuit board 210 and a second circuit board 220 are respectively provided with a plurality of functional devices 204 that generate heat. The functional devices 204 may include chips, sensors, and the like. In some embodiments, the functional devices 204 may be chips, for example, including a control chip or a driver chip.

As illustrated in FIG. 4, in some embodiments, the first circuit board 210 includes a first area 201, a second area 202, and a third area 203. The fan 1 of the heat dissipation assembly 300 cooperates with the first area 201, the plurality of heat conduction sheets 23 of the heat conduction member 2 cooperates with the second area 202, and the at least one flow outlet 21 of the plurality of flow outlets 21 cooperates with the third area 203. In some embodiments, the fan 1 is made of a thermally conductive material, and the fan 1 is in contact with the first area 201 to conduct heat generated by the first area 201 and conduct the heat to the heat conduction member 2. Specifically, the housing 13 of the fan 1 directly or indirectly contacts the functional devices 204 in the first area 201, to achieve heat conduction of the heat generated in the first area 201 and conduct the heat to the heat conduction member 2. Further, in some embodiments, the heat conduction member 2 is in contact with the second area 202 to achieve heat conduction generated by the second area 202 and conduct the heat to the at least one flow outlet 21. Specifically, the heat conduction member 2 directly or indirectly contacts the functional devices 204 in the second area 202 through the plurality of heat conduction sheets 23 and/or the main body 22 to conduct heat generated in the second area 202 to the at least one flow outlet 21. The airflow from the at least one flow outlet 21 flows directly or indirectly to the third area 203 to dissipate heat from the functional devices 204 in the third area 203.

To increase the heat dissipation speed in the third area 203, in some embodiments, at least one set of the plurality of flow outlets 21 may be aligned with the third area 203. Correspondingly, the third area 203 may be directly aligned with at least one flow outlet 21 of the plurality of flow outlets 21 and have high heat dissipation efficiency. In another embodiment, at least one flow outlet 21 of the plurality of flow outlets 21 may be arranged close to the third area 203, thereby increasing the heat dissipation speed of the third area 203.

Specifically, in some embodiments, the airflow from the first flow outlet 211 of the heat dissipation assembly 300 may be aligned with or close to the third area 203.

When the heat of the second circuit board 220 is dissipated by the heat dissipation assembly 300, the plurality of heat conduction sheets 23 and/or the main body 22 of the heat conduction member 2 may be in contact with the second circuit board 220 to conduct the heat generated by the second circuit board 220 to the flow outlets 21. Specifically, the heat conduction member 2 may directly or indirectly contact the functional devices 204 on the second circuit board 220 through the plurality of heat conduction sheets 23 and/or the main body 22, to conduct the heat generated by the second circuit board 220 to the plurality of flow outlets 21.

In some embodiments, the unmanned aerial vehicle may include a main control board and a motor drive circuit board. During the flight of the unmanned aerial vehicle, the main control board and the motor drive circuit board may be the main heat generating sources in the receiving space 110. Optionally, the first circuit board 210 is the main control board, and the second circuit board 220 is the motor drive circuit board, such that the heat generated by the main control board and the motor drive circuit board are dissipated through the heat dissipation assembly 300 to prevent a large amount of heat accumulation in the receiving space 110. When the unmanned aerial vehicle is an unmanned plane, the main control board is the flight controller of the unmanned plane.

Further, the circuit board 200 may further include a third circuit board 230. The third circuit board 230 may include an inertial measurement module (IMU) and/or a GPS module, to acquire posture information and location information of the unmanned aerial vehicle. The third circuit board 230 may also be fixedly connected to the inner sidewall of the vehicle body 100.

In some embodiments, the first airflow exit 121 may be connected to the receiving space 110. The first flow outlet 211 and the first airflow exit 121 may be disposed alternately, and the third area 203 of the first circuit board 210 may be disposed between the first airflow exit 121 and the first flow outlet 211. The airflow flowing out from the first air outlet 211 may pass through the third area 203 and then be led out by the first airflow exit 121. To better dissipate heat in the third area 203 of the first circuit board 210, the size of the first flow outlet 211 in some embodiments may match the third area 203.

Further, the second airflow exit 122 is connected to the second flow outlet 212. Correspondingly, the second flow outlet 212 is connected to the second airflow exit 122, and the airflow from the second flow outlet 212 is directly led out through the second airflow exit 122. The third airflow exit 123 is connected to the third flow outlet 213. Correspondingly, the third flow outlet 213 is connected to the third airflow exit 123, and the airflow from the third flow outlet 213 is directly led out by the third airflow exit 123. Optionally, the second flow outlet 212 and the second airflow exit 122, and the third flow outlet 213 and the third airflow exit 123 are all hermetically connected, such that the airflow through the second flow outlet 212 and the third flow outlet 213 may be led to outside of the vehicle body 100 as much as possible.

In some embodiments, as illustrated in FIG. 7 to FIG. 10, the vehicle body 100 is also provided with one or more air inlet members 130. Further referring to FIG. 2, the fan 1 includes the first air inlet 12, and the first air inlet 12 cooperates with the one or more air inlet member s 130, such that the airflow outside the vehicle body 100 enters the first air inlet 12 from the one or more air inlet members 130.

The one or more air inlet members 130 may be include a plurality of air inlet members 130, such as two, three, four or more. In some embodiments, one or more of the air inlet members 130 may be provided at a side of the second sidewall 150 away from the rear of the vehicle body 100, and a remaining air inlet member(s) 130 may be provided at a side of the third sidewall 160 away from the rear of the vehicle body 100. Optionally, the fan 1 may include a plurality of first air inlets 12, for example, two, three, four or more first air inlets 12.

The air inlet members 130 may be of different types. For example, in some embodiments, each air inlet member 130 may include a plurality of second air inlets (the second air inlets may be circular, square, or another shape). In some other embodiments, each air inlet member 130 may also be a grid structure or a gap at the connection of the housing for mounting the vehicle body 100.

In some embodiments, as illustrated in FIG. 11, the unmanned aerial vehicle further includes a plurality of arms 400 connected to the outer sidewall of the vehicle body 100 and a propeller connected to each arm 400, which drives the vehicle body 100 to move.

As shown in FIG. 11, the unmanned aerial vehicle further includes a gimbal 500 connected to the front cover 104, and the gimbal 500 may be used to carry a camera device. The gimbal 500 can be a two-axis gimbal or a three-axis gimbal. The camera device may be an image capture device or a photographing device (such as a camera, a camcorder, an infrared camera device, an ultraviolet camera device, or the like), an audio capture device (for example, a parabolic reflection microphone), an infrared camera device, etc. The camera device can provide static sensing data (such as pictures) or dynamic sensing data (such as videos). The camera device may be mounted on the gimbal 500, such that the gimbal 500 controls the rotation of the camera device.

As shown in FIG. 11, the unmanned aerial vehicle further includes a battery assembly 600 arranged at the vehicle body 100 to supply power to the unmanned aerial vehicle. In some embodiments, a storage slot may be provided at the side of the front cover 104 away from the storage space 110, and the battery assembly 600 may be fixed in the storage slot.

In various embodiments, the unmanned aerial vehicle may be an unmanned plane or another type of remote aerial vehicle.

In the present disclosure, the heat dissipation assembly 300 may be disposed in the receiving space 110. The airflow from the fan 1 in the heat dissipation assembly 300 may pass through the heat conduction member 2 and then flow out from at least two sets of flow outlets 21 facing different directions. On the one hand, the heat conduction member 2 may absorb the heat generated by the circuit board 200, and the airflow flowing through the heat conduction member 2 may fully contact the heat conduction member 2 to achieve a sufficient heat exchange. The utilization rate of the airflow may be improved and the heat exchange effect may be enhanced. On the other hand, the airflow flowing out from the flow outlets 21 can also directly dissipate the heat generated by the main heat generation elements in the electronic device, and the heat dissipation efficiency may be high. The heat dissipation assembly 300 of the present disclosure can use airflow for heat dissipation more efficiently and evenly.

In the present disclosure, “up” and “down” should be understood as the “up” and “down” of the heat dissipation device formed by mounting the second circuit board 220, the heat dissipation assembly 300, and the first circuit board 210 from top to bottom.

In this disclosure, terms such as “first” and “second” are only used to distinguish one entity or operation from another entity or operation, and do not necessarily require or imply existence of any such relationship or sequence among these entities or operations. The terms “include,” “comprise” or any other variants thereof are intended to cover non-exclusive inclusion, so that a process, method, article, or device including a series of elements not only includes those elements, but also includes other elements not explicitly listed, or also includes elements inherent to such process, method, article, or device. If there are no more restrictions, the element associated with “including a . . . ” does not exclude the existence of other identical elements in the process, method, article, or device that includes the element.

Other embodiments of the disclosure will be apparent to those skilled in the art from consideration of the specification and practice of the embodiments disclosed herein. It is intended that the specification and examples be considered as example only and not to limit the scope of the disclosure, with a true scope and spirit of the invention being indicated by the following claims.

What is claimed is:

1. A heat dissipation assembly comprising:
a fan including an air outlet; and
a heat conduction member connected to the fan, an end of the heat conduction member cooperating with the air outlet of the fan and another end of the heat conduction member being provided with a plurality of flow outlets that are grouped into at least two groups facing different directions;
wherein airflow from the air outlet of the fan flows through the heat conduction member and then flows out through the plurality of flow outlets.

2. The heat dissipation assembly according to claim 1, wherein:
the plurality of flow outlets include a first flow outlet, a second flow outlet, and a third flow outlet having different flow outlet directions;
the second flow outlet and the third flow outlet are disposed at two sides of the first flow outlet, respectively; and
a size of the first flow outlet gradually increases in a direction away from the air outlet of the fan.

3. The heat dissipation assembly according to claim 1, further comprising a damping member disposed between a case of the fan and a main body of the heat conduction member.

4. An unmanned aerial vehicle comprising:
a vehicle body including a receiving space and provided with an airflow exit;
a circuit board; and
a heat dissipation assembly connected to the circuit board;
wherein:
the circuit board and the heat dissipation assembly are accommodated in the receiving space;
the heat dissipation assembly includes:
a fan including an air outlet; and
a heat conduction member connected to the fan, an end of the heat conduction member cooperating with the air outlet of the fan and another end of the heat conduction member being provided with a plurality of flow outlets that are grouped into at least two groups facing different directions; and
airflow from the air outlet of the fan flows through the heat conduction member and then flows out from the plurality of flow outlets.

5. The unmanned aerial vehicle according to claim 4, wherein:
the plurality of flow outlets include a first flow outlet, a second flow outlet, and a third flow outlet; and
the second flow outlet and the third flow outlet are disposed at two sides of the first flow outlet, respectively.

6. The unmanned aerial vehicle according to claim 5, wherein flow outlet directions of the first flow outlet, the second flow outlet, and the third flow outlet are different from each other.

7. The unmanned aerial vehicle according to claim 6, wherein a size the first flow outlet gradually increases in a direction away from the air outlet of the fan.

8. The unmanned aerial vehicle according to claim 5, wherein the airflow exit is one of a plurality of airflow exits including a first airflow exit, a second airflow exit, and a third airflow exit corresponding to the first flow outlet, the second flow outlet, and the third flow outlet respectively.

9. The unmanned aerial vehicle according to claim 8, wherein:
the vehicle body includes a first sidewall, a second sidewall, and a third sidewall;
the first sidewall is disposed at a rear of the vehicle body;
the second sidewall and the third sidewall are disposed at two sides of the first sidewall, respectively;
the first airflow exit is opened at the first sidewall;
the second airflow exit is opened at a side of the second sidewall close to the rear of the vehicle body; and
the third airflow exit is opened at a side of the third sidewall close to the rear of the vehicle body.

10. The unmanned aerial vehicle according to claim 8, wherein:
the first airflow exit is one of a plurality of first airflow exits;
the second airflow exit is one of a plurality of second airflow exits; and/or
the third airflow exit is one of a plurality of third airflow exits.

11. The unmanned aerial vehicle according to claim 4, wherein:
the heat conduction member includes a main body and a plurality of heat conduction sheets provided at the main body and arranged at intervals, each of the plurality of heat conduction sheets extending from an end of the main body close to the air outlet of the fan to one of the plurality of the plurality of flow outlets; and
the airflow from the air outlet of the fan flows through the heat conduction sheets and then flows out through the plurality of flow outlets.

12. The unmanned aerial vehicle according to claim 11, wherein:
each of the plurality of heat conduction sheets is provided with an auxiliary heat dissipation rib at a side away from the main body.

13. The unmanned aerial vehicle according to claim 4, wherein:
the fan includes a heat-conducting case and blades provided at the case;
the heat conduction member includes a main body connected to the case; and
the heat dissipation assembly further includes an elastic element disposed between the case and the main body.

14. The unmanned aerial vehicle according to claim 4, wherein the heat dissipation assembly further includes a cover covering the heat conduction member and provided with exits at positions corresponding to the plurality of flow outlets.

15. The unmanned aerial vehicle according to claim 4, wherein:
the fan further includes a first air inlet;
the vehicle body further includes a plurality of air inlet members cooperating with the first air inlet and each including a plurality of second air inlets;
the vehicle body further includes a first sidewall, a second sidewall, and a third sidewall;
the first sidewall is disposed at a rear of the vehicle body;
the second sidewall and the third sidewall are disposed at two sides of the first sidewall, respectively;
one or more of the air inlet members are disposed at a side of the second sidewall away from the rear of the vehicle body; and
another one or more of the air inlet members are disposed at a side of the third sidewall away from the rear of the vehicle body.

16. The unmanned aerial vehicle according to claim 4, wherein:
the circuit board includes a first circuit board attached to one side of the heat dissipation assembly and a second circuit board attached to another side of the heat dissipation assembly; and
a main body of the heat dissipation assembly is connected to the first circuit board.

17. The unmanned aerial vehicle according to claim 16, wherein:
the first circuit board includes a plurality of functional devices that generate heat;
the first circuit board includes a first region, a second region, and a third region;
the fan of the heat dissipation assembly cooperates with the first region;
a heat conduction sheet of the heat conduction member cooperates with the second region;
at least one of the plurality of flow outlets cooperates with the third region.
at least one of the at least two groups of the plurality of flow outlets is aligned with or is close to the third region.

18. The unmanned aerial vehicle according to claim 17, wherein:
the fan is made of a thermally conductive material, and contacts the first region of the first circuit board to conduct heat generated in the first region to the heat conduction member; and/or
the heat conduction sheet of the heat conduction member contacts the second region of the first circuit board to conduct heat generated in the second region to the plurality of flow outlets.

19. The unmanned aerial vehicle according to claim 17, wherein:
one of the plurality of functional devices includes a chip.

20. The unmanned aerial vehicle according to claim 16, wherein:
the second circuit board includes a plurality of functional devices that generate heat; and
a heat conduction sheet of the heat conduction member contacts the second circuit board to conduct heat generated by the second circuit board to the plurality of flow outlets;
the first circuit board includes a main control board; and
the second circuit board includes a motor driving circuit board.
